(19) United States
(12) Patent Application Publication
(10) Pub. No.: US 2025/0345970 A1
(43) Pub. Date: Nov. 13, 2025

(54) FILM FORMING APPARATUS, FILM FORMING METHOD, AND ARTICLE MANUFACTURING METHOD

(71) Applicant: CANON KABUSHIKI KAISHA, Tokyo (JP)

(72) Inventor: KAZUKI ARAI, Tochigi (JP)

(21) Appl. No.: 19/196,089

(22) Filed: May 1, 2025

(30) Foreign Application Priority Data
May 7, 2024 (JP) 2024-075412

(51) Int. Cl. B29C 35/00; B29C 35/02

(52) U.S. Cl. CPC B29C 35/002; B29C 35/02

(57) ABSTRACT

A film forming apparatus includes a movable stage; a substrate holder supported by the movable stage and configured to hold a substrate; a coupling configured to couple the movable stage and the substrate holder; and a curing unit configured to cure a curable composition on the substrate, wherein the coupling includes: a kinematic coupling; and an attraction force generator configured to generate, between the movable stage and the substrate holder, an attraction force for fixing the substrate holder to the movable stage.

### BACKGROUND

### Technical Field

The present disclosure relates to film forming apparatus, a film forming method, and an article manufacturing method.

### Description of the Related Art

A technique of planarizing the surface of a substrate by forming a film on the substrate using a spin coater has widely been used. This method is not sufficient for planarizing a step on the substrate on the order of nano-scale. A planarization method using an imprint technique has received attention. In the planarization method using the imprint technique, a flat member called a superstrate is brought into contact with a curable composition applied to the surface of a substrate to spread the curable composition, and the curable composition is then cured, thereby forming a planarization film.

The curable composition can be cured by being irradiated with curing energy such as light. For this reason, when a number of substrates are processed, an undesirable temperature distribution may occur on a movable stage that holds the substrate and a substrate holder supported by the movable stage. This may deform the substrate holder, and the deformation may cause deformation of the substrate. If a planarization film is formed on a substrate in a deformed state, and the substrate then returns to a thermally equilibrium state, the degree of planarization of the surface of the planarization film may deteriorate. Note that the problem derived from deformation of the movable stage, the substrate holder, and the like may occur even in an imprint apparatus that transfers a pattern to a substrate or an exposure apparatus that exposes a substrate by projecting the pattern of an original to the substrate by a projection optical system.

Japanese Patent Laid-Open No. 2008-23868 describes irradiating a resin layer with an energy line in a state in which the resin layer is pressed by a transfer mold, interrupting the irradiation of the energy line halfway through curing of the resin layer and canceling pressing to release stress, and then resuming the irradiation of the energy line to the resin layer.

### SUMMARY

The present disclosure provides a technique advantageous for reducing deformation of a substrate holder supported by a movable stage.

According to an aspect of the present disclosure, there is provided a film forming apparatus comprising: a movable stage; a substrate holder supported by the movable stage and configured to hold a substrate; a coupling configured to couple the movable stage and the substrate holder; and a curing unit configured to cure a curable composition on the substrate, wherein the coupling includes: a kinematic coupling; and an attraction force generator configured to generate, between the movable stage and the substrate holder, an attraction force for fixing the substrate holder to the movable stage.

Features of the present disclosure will become apparent from the following description of embodiments with reference to the attached drawings. The following description of embodiments are described by way of example.

### BRIEF DESCRIPTION OF THE DRAWINGS

FIG. 1 is a view schematically showing the configuration of a film forming apparatus according to an embodiment;

FIG. 2 is view showing a substrate holder viewed from the lower side;

FIG. 3 is view showing a movable stage 4 viewed from above;

FIG. 4 is a view showing an example of the configuration of an attraction force generator;

FIG. 5 is a view showing another example of the configuration of the attraction force generator; and

FIG. 6 is a flowchart showing the operation (film forming processing) of the film forming apparatus.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In this specification and drawings, directions are indicated on an XYZ coordinate system that has, as an XY plane, a plane parallel to the surface of a substrate held by a substrate holder. Directions parallel to the X-axis, the Y-axis, and the Z-axis of the XYZ coordinate system are defined as the X direction, the Y direction, and the Z direction, respectively. In addition, the +Z direction is defined as up, and the −Z direction is defined as down.

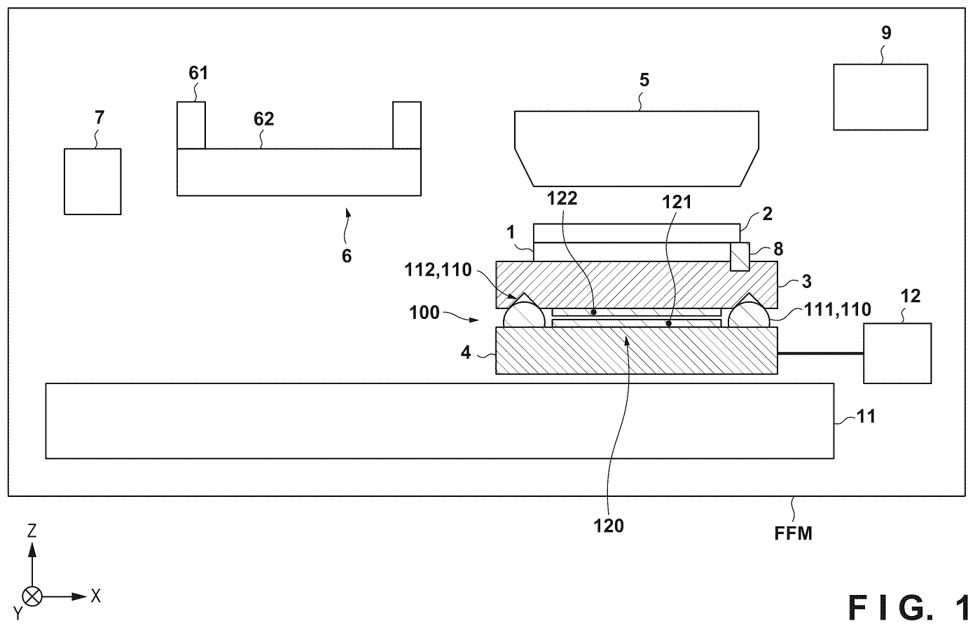

FIG. 1 schematically shows the configuration of a film forming apparatus FFM according to an embodiment. The film forming apparatus FFM can be configured to form a film of a cured product of a curable composition on a substrate 1. The film forming apparatus FFM can be formed as, for example, a planarization apparatus or an imprint apparatus, and an example in which the film forming apparatus FFM is formed as a planarization apparatus will be described below. If the film forming apparatus FFM is formed as an imprint apparatus, a mold having a pattern is used in place of a planarization member 2 to be described below, and the pattern can be transferred to the curable composition on the substrate 1.

The substrate 1 can be, for example, a plate-shaped member made of glass, silica glass, ceramic, a metal, a semiconductor (for example, silicon or a compound semiconductor), or a resin, or a member having one or a plurality of layers on such a plate-shaped member. The substrate 1 can include a plurality of shot regions. The substrate 1 can also include marks used to measure distortion of each shot region, the array of the plurality of shot regions, and the like.

The planarization member 2 is made of, for example, glass, ceramic, a metal, a semiconductor, a resin, or the like. The planarization portion on the surface of the planarization member 2 comes into contact with the curable composition on the substrate 1, and a flat liquid film can be formed by surface tension of the curable composition. The outer diameter (size) of the planarization member 2 is preferably equal to or larger than the outer diameter (size) of the substrate 1.

The film forming apparatus FFM can include an application unit 7 that applies the curable composition onto the substrate 1. However, the substrate 1 to which the curable composition is applied by an external apparatus may be provided to the film forming apparatus FFM. The curable composition is a composition that is cured when curing energy is given. As the curing energy, an electromagnetic wave, heat, or the like is used. The electromagnetic wave is, for example, light such as infrared rays, visible rays, or ultraviolet rays whose wavelength is selected from the range of 10 nm or more and 1 mm or less. The curable composition to be cured by light contains at least a polymerizable compound and a photopolymerization initiator and may contain a nonpolymerizable compound or a solvent as needed. The nonpolymerizable compound is at least a type selected from the group consisting of a sensitizer, a hydrogen donor, an internal mold release agent, a surfactant, an antioxidant, and a polymer component. The viscosity of the curable composition (the viscosity at 25° C.) is, for example, 1 mPa·s or more and 100 mPa·s or less. The application unit 7 can be configured to apply droplets of the curable composition onto the substrate 1. The term “application” includes, for example, an operation of discharging the droplets of the curable composition and thus discretely arranging the droplets on the substrate 1. In an example, the curable composition can be applied onto the substrate 1 by discharging the droplets of the curable composition from the application unit 7 while driving the substrate 1 by a driving mechanism 12.

The film forming apparatus FFM can include an operation unit 6 that operates the planarization member 2 as a kind of mold used to mold the curable composition applied onto the substrate 1. The planarization member 2 can also be called a superstrate. The operation unit 6 can be configured to execute a contact step of bringing the planarization member 2 into contact with the curable composition applied onto the substrate 1, and a separation step of separating the planarization member 2 from a film made of a cured product of the curable composition on the substrate 1. However, a unit that executes the contact step and a unit that executes the separation step may be provided separately. The film forming apparatus FFM may further include a separation mechanism 8 that separates the planarization member 2 from the film made of the cured product of the curable composition on the substrate 1. In this case, the separation mechanism 8 operates to cut the bond between the planarization member 2 and the film made of the cured product of the curable composition on the substrate 1 and, after that, the operation unit 6 can operate to recover the planarization member 2 from the substrate 1. The separation mechanism 8 can be provided on, for example, a substrate holder 3 to be described later. The operation of cutting the bond between the planarization member 2 and the film made of the cured product of the curable composition on the substrate 1 may be performed by both the separation mechanism 8 and the operation unit 6. The operation unit 6 can include a chuck 62 that holds the planarization member 2, and a driving mechanism 61 that lifts/lowers the chuck 62.

The film forming apparatus FFM can include a curing unit 5 that cures the curable composition on the substrate 1. The curing unit 5 can cure the curable composition by applying curing energy to the curable composition on the substrate 1. As the curing energy, various kinds of energies can be employed, as described above. The curing unit 5 can be configured to, for example, irradiate the curable composition between the substrate 1 and the planarization member 2 with the curing energy through the planarization member 2.

The film forming apparatus FFM can include a movable stage 4, the substrate holder 3 supported by the movable stage 4, and a coupling 100 that couples the movable stage 4 and the substrate holder 3. The substrate holder 3 can include a chuck (for example, a vacuum chuck or an electrostatic chuck) that holds the substrate 1. The film forming apparatus FFM can also include the driving mechanism 12 that drives the substrate 1 by driving the movable stage 4. The film forming apparatus FFM may include a base 11, and the driving mechanism 12 can drive the movable stage 4 such that the movable stage 4 moves along the upper surface of the base 11. The driving mechanism 12 can drive the substrate holder 3 (substrate 1) to an application position at which an application step by the application unit 7 is executed, a curing position at which a curing step by the curing unit 5 is executed, and an operation position at which the contact step and the separation step by the operation unit 6 are executed. Also, the driving mechanism 12 can drive the substrate holder 3 (substrate 1) to a position at which the substrate 1 is loaded and unloaded.

The coupling 100 can include a kinematic coupling 110. The coupling 100 can also include, between the movable stage 4 and the substrate holder 3, an attraction force generator 120 that generates an attraction force for fixing the substrate holder 3 to the movable stage 4. “Attraction force” is a term including, for example, a vacuum attraction force, an electromagnetic attraction force, and an electrostatic attraction force.

When the curing unit 5 irradiates the curable composition with the curing energy, not only the substrate 1, the curable composition, and the planarization member 2 but also the substrate holder 3 and the movable stage 4 can be heated. The substrate holder 3 and the movable stage 4 can be deformed (expanded) by heat. Note that the substrate holder 3 includes, for example, a pin chuck, and even if the substrate holder 3 is deformed (expanded) by heat, flatness of the surface that supports the substrate 1 can be maintained at high accuracy.

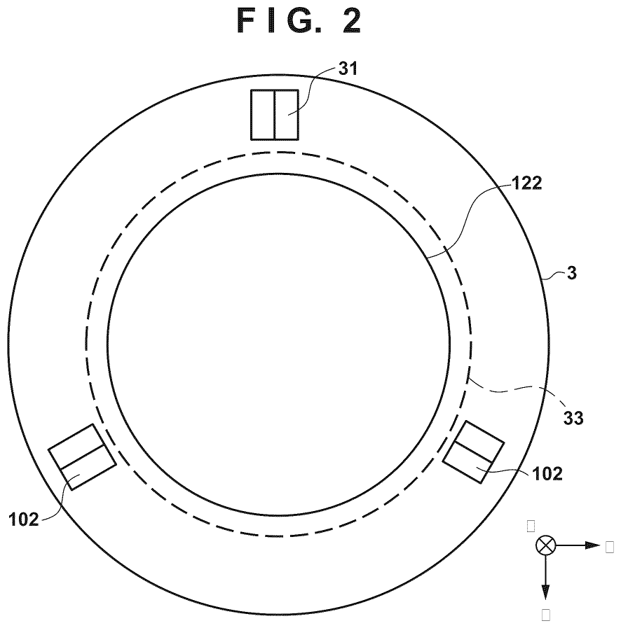

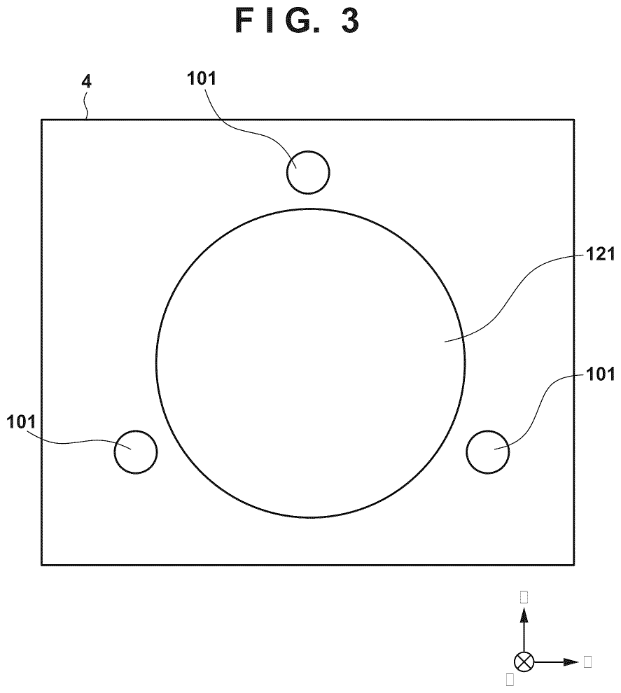

FIGS. 2 and 3 show an example of the configuration of the kinematic coupling 110. Here, FIG. 2 is a view showing the substrate holder 3 viewed from the lower side, and FIG. 3 is a view showing the movable stage 4 viewed from above. The kinematic coupling 110 can be configured to constrain the substrate holder 3 concerning 6 degrees of freedom. The kinematic coupling 110 includes, for example, a plurality of (typically, three) constraint portions, and each constraint portion can be formed by a V groove 112, and a ball 111 that engages with the V groove 112. The V grooves 112 can be provided on the substrate holder 3, and the balls 111 can be provided on the movable stage 4. Alternatively, the V grooves 112 can be provided on the movable stage 4, and the balls 111 can be provided on the substrate holder 3. In each constraint portion, the V groove 112 and the ball 111 are made to abut against each other by the gravity acting on the substrate holder 3, and the substrate holder 3 is thus positioned with respect to the movable stage 4 concerning 6 degrees of freedom. The V grooves 112 can be formed by machining the substrate holder 3 or the movable stage 4. Alternatively, components having the V grooves 112 can be fastened to the substrate holder 3 or the movable stage 4. The balls 111 can be fastened to the movable stage 4 or the substrate holder 3.

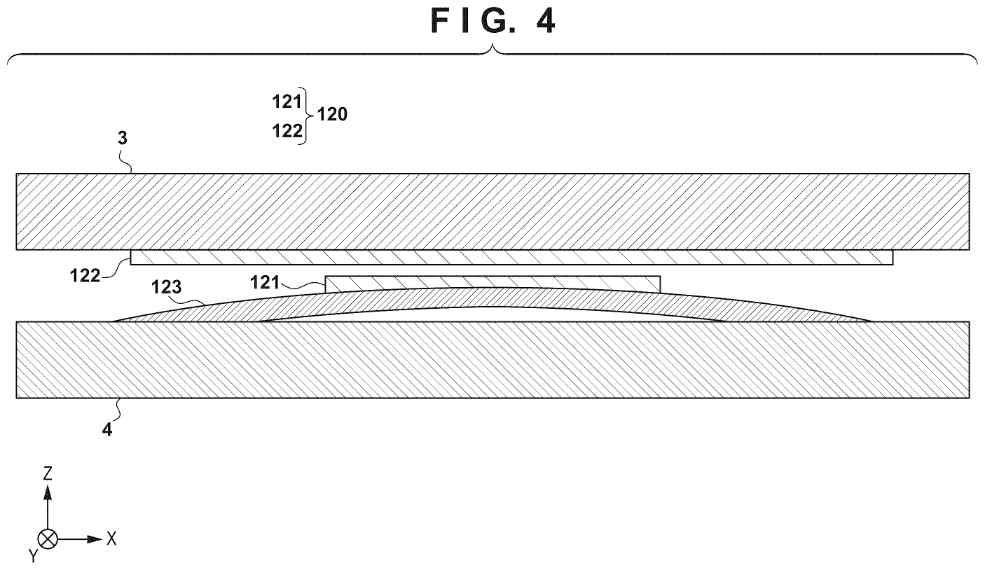

FIG. 4 schematically shows an example of the configuration of the attraction force generator 120. The attraction force generator 120 includes a first portion 121 provided on the movable stage 4, and a second portion 122 provided on the substrate holder 3, and can generate an attraction force between the first portion 121 and the second portion 122. The coupling 100 may further include an elastic member 123. The elastic member 123 can support the first portion 121 or the second portion 122 such that when the attraction force generator 120 generates an attraction force, the first portion 121 and the second portion 122 come into contact with each other, and when the attraction force generator 120 does not generate an attraction force, the first portion 121 and the second portion 122 do not come into contact with each other.

The elastic member 123 can be, for example, a spring such as a leaf spring. Generation of the attraction force by the attraction force generator 120 can be controlled by a controller 9 to be described later. The attraction force generator 120 can be configured to generate, for example, an electrostatic attraction force. In an example, the first portion 121 of the attraction force generator 120 is an electrode for generating an electrostatic attraction force, and the second portion 122 of the attraction force generator 120 is a pad to be attracted by the first portion 121. When the attraction force generator 120 is not generating the attraction force, the movable stage 4 and the substrate holder 3 are coupled with a first coupling force by the kinematic coupling 110. On the other hand, when the attraction force generator 120 is generating the attraction force, the movable stage 4 and the substrate holder 3 are coupled with a second coupling force larger than the first coupling force by the kinematic coupling 110 and the attraction force generator 120. The attraction force generator 120 may be configured to adjust the magnitude of the attraction force to be generated.

The attraction force generator 120 may generate, for example, an electromagnetic attraction force. In this case, to generate a controllable electromagnetic attraction force between the first portion 121 and the second portion 122, at least one of the first portion 121 and the second portion 122 is formed by an electromagnet. In an example, the first portion 121 can be formed by an electromagnet, and the second portion can be formed by an iron core.

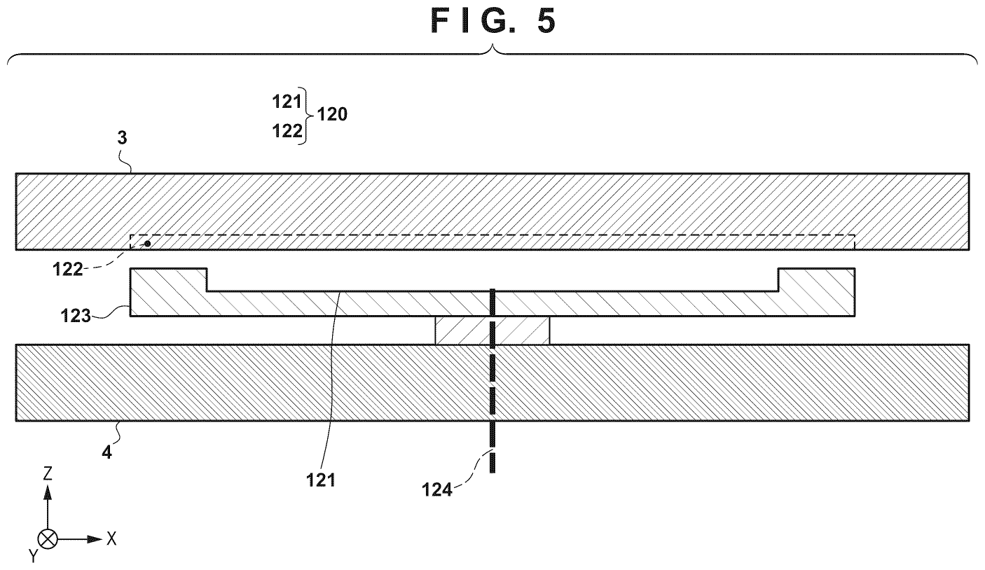

The attraction force generator 120 may generate a vacuum attraction force. FIG. 5 schematically shows a configuration example in which the attraction force generator 120 generates a vacuum attraction force. In the example shown in FIG. 5, the first portion 121 and the elastic member 123 are integrated, and the elastic member 123 is provided with a vacuum attraction line 124. The second portion 122 can be formed by the lower surface (lower portion) of the substrate holder 3.

The elastic member 123 can be, for example, a deformable member made of a resin or a metal. In place of the elastic member 123, a slightly deformable component, for example, a piezoelectric element may be used.

As exemplarily shown in FIG. 2, the substrate holder 3 can have a circular to a disc-like shape. However, the substrate holder 3 may have another shape, for example, a rectangular or cuboid shape. The three V grooves 112 can be arranged at an interval of 120° on a virtual circle that is concentric to the center axis of a substrate holding region 33 where the substrate 1 is held, and is larger than the outer shape of the substrate 1. Also, each V groove 112 can be arranged such that its center line (a line forming a valley) is directed to the center axis of the holding region 33. Each ball 111 is arranged at a position facing the V groove 112 paired therewith.

When the substrate 1 is heated by irradiation of curing energy by the curing unit, and the heat of the substrate 1 is transmitted to the substrate holder 3 and the movable stage 4, the substrate holder 3 and the movable stage 4 can individually be deformed. However, if the movable stage 4 and the substrate holder 3 are coupled only by the kinematic coupling 110, the substrate holder 3 is not affected by the deformation of the movable stage 4. Hence, the deformation of the substrate 1 and the substrate holding surface (a surface defined by a portion coming into contact with the substrate 1) of the substrate holder 3 is very small and negligible. For this reason, the flatness of the surface of the film made of the cured product of the curable composition formed on the substrate 1 can be maintained even if the temperature of the substrate 1 returns to a thermally equilibrium state.

It is preferable that the second portion 122 has, for example, a circular shape concentric to the center axis of the substrate holding region 33 and its radius is smaller than the radius of the substrate 1. The second portion 122 may be formed by a plurality of concentric members.

The film forming apparatus FFM can include a controller 9. The controller 9 can be formed by, for example, a PLD (the abbreviation of Programmable Logic Device) such as an FPGA (the abbreviation of Field Programmable Gate Array), or an ASIC (the abbreviation of Application Specific Integrated Circuit), or a general-purpose or dedicated computer in which a program is installed, or a combination of some or all of these. The controller 9 controls the application unit 7, the operation unit 6, the curing unit 5, the driving mechanism 12, and the attraction force generator 120. Thus, the controller 9 controls film forming processing of forming, on the substrate 1, a cured product film made of the cured product of the curable composition. The film forming processing can include, for example, an application step of applying a curable composition to a substrate, a contact step of bringing a planarization member (mold) into contact with the curable composition on the substrate, a curing step of curing the curable composition, and a separation step of separating the planarization member from a cured product film of the curable composition. The film forming processing can further include a driving step of driving the substrate. In the curing step, the attraction force generator 120 is preferably set in a non-operation state. On the other hand, in the contact step and the driving step, the attraction force generator 120 is preferably set in an operation state. In the application step, the attraction force generator 120 can be controlled in accordance with the acceleration of the movable stage 4. For example, in a case of an acceleration at which the positioning accuracy of the substrate holder 3 with respect to the movable stage 4 is maintained by the kinematic coupling 110 even if the attraction force generator 120 is in the non-operation state, the attraction force generator 120 can be set in the non-operation state. On the other hand, in a case of an acceleration at which the positioning accuracy of the substrate holder 3 with respect to the movable stage 4 is not guaranteed if the attraction force generator 120 is in the non-operation state, the attraction force generator 120 can be set in the operation state.

The controller 9 can be configured to control the state of the attraction force generator 120 in accordance with the progress of film forming processing. In one aspect, the controller 9 sets the attraction force generator 120 in the non-operation state in, for example, at least the curing step. In another aspect, the controller 9 can be configured to make the attraction force generated by the attraction force generator 120 in the curing step smaller than the attraction force generated by the attraction force generator 120 in the driving step.

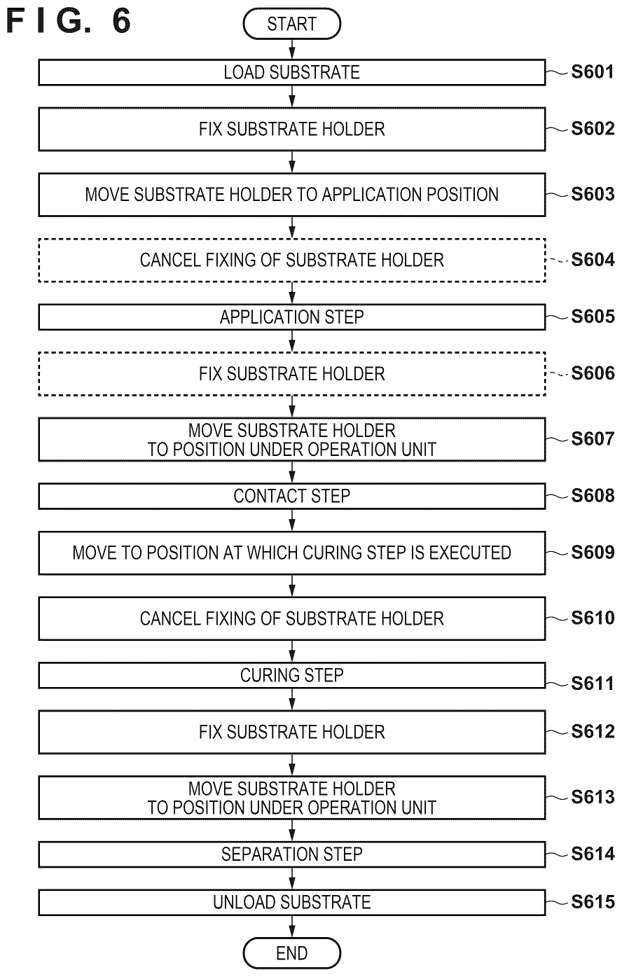

FIG. 6 exemplarily shows the procedure of film forming processing controlled by the controller 9. In step S601, the controller 9 controls the driving mechanism 12 such that the substrate holder 3 is arranged at a receiving position of the substrate 1, and receives supply of the substrate 1 to the substrate holder 3. Alternatively, the controller 9 may cause a substrate conveying robot (not shown) to supply the substrate 1. In step S602, the controller 9 sets the attraction force generator 120 in the operation state and causes it to fix the substrate holder 3 to the movable stage 4 with the second coupling force. In step S603, the controller 9 controls the driving mechanism 12 such that the substrate holder 3 (substrate 1) is arranged at an application position. Step S604 is an arbitrary step, and the controller 9 sets the attraction force generator 120 in the non-operation state and cancels fixing of the substrate holder 3 to the movable stage 4. Thus, the coupling force of the substrate holder 3 to the movable stage 4 is only the coupling force by the kinematic coupling 110, that is, the first coupling force smaller than the second coupling force. Note that in step S604, the controller 9 may make the attraction force generated by the attraction force generator 120 smaller than the attraction force in steps S602 and S603. In step S605, the controller 9 controls the application unit 7 and the driving mechanism 12 such that the curable composition is applied onto the substrate 1. Step S606 is executed when step S604 is executed. The controller 9 sets the attraction force generator 120 in the operation state and causes it to fix the substrate holder 3 to the movable stage 4 with the second coupling force.

In step S607, the controller 9 controls the driving mechanism 12 such that the substrate holder 3 (substrate 1) is arranged at a position under the operation unit 6. In step S608, the controller 9 controls the operation unit 6 to bring the planarization member 2 into contact with the curable composition on the substrate 1. Note that in step S608, if the first coupling force is sufficient as the coupling force of the substrate holder 3 to the movable stage 4, the controller 9 may set the attraction force generator 120 in the non-operation state. In this case, the controller 9 sets the attraction force generator 120 in the operation state after the end of step S608.

In step S609, the controller 9 controls the driving mechanism 12 such that the substrate holder 3 (substrate 1) is arranged at a position under the curing unit 5. In step S610, the controller 9 sets the attraction force generator 120 in the non-operation state and cancels fixing of the substrate holder 3 to the movable stage 4. Thus, the coupling force of the substrate holder 3 to the movable stage 4 is only the coupling force by the kinematic coupling 110, that is, the first coupling force smaller than the second coupling force. In step S611, the controller 9 controls the curing unit 5 such that the curable composition between the substrate 1 and the planarization member 2 is irradiated with curing energy, thereby curing the curable composition. Thus, a cured product film made of the cured product of the curable composition is formed.

In step S612, the controller 9 sets the attraction force generator 120 in the operation state and causes it to fix the substrate holder 3 to the movable stage 4 with the second coupling force. In step S613, the controller 9 controls the driving mechanism 12 such that the substrate holder 3 (substrate 1) is arranged at a position under the operation unit 6. In step S614, the controller 9 controls the operation unit 6 and the separation mechanism 8 to separate the planarization member 2 from the cured product on the substrate 1. In step S614, the substrate holder 3 needs to be coupled to the movable stage 4 with the second coupling force. In step S615, the controller 9 controls the driving mechanism 12 such that the substrate holder 3 is arranged at a transfer position of the substrate 1, and transfers the substrate 1 from the substrate holder 3 to the substrate conveying robot.

An article manufacturing method for manufacturing an article such as a semiconductor device will be described below. The article manufacturing method can include a film forming step of forming a cured product film on a substrate using the film forming apparatus FFM, and a processing step of performing processing for the substrate that has undergone the film forming step, thereby obtaining an article. The film forming apparatus FFM may be formed as a planarization apparatus or may be formed as an imprint apparatus. If the film forming apparatus FFM is formed as a planarization apparatus, a planarization film is formed on a substrate having unevenness by the film forming apparatus FFM, and the subsequent processing step can include a lithography step using an exposure apparatus. If the film forming apparatus FFM is formed as an imprint apparatus, a pattern made of a cured product film is formed on a substrate by imprint processing.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-075412, filed May 7, 2024, which is hereby incorporated by reference herein in its entirety.

What is claimed is:

1. A film forming apparatus comprising:
a movable stage;
a substrate holder supported by the movable stage and configured to hold a substrate;
a coupling configured to couple the movable stage and the substrate holder; and
a curing unit configured to cure a curable composition on the substrate,
wherein the coupling includes:
a kinematic coupling; and
an attraction force generator configured to generate, between the movable stage and the substrate holder, an attraction force for fixing the substrate holder to the movable stage.

2. The apparatus according to claim 1, further comprising a controller configured to control a state of the attraction force generator in accordance with progress of processing of forming a film of the curable composition on the substrate.

3. The apparatus according to claim 2, wherein
the processing includes curing the curable composition by applying curing energy to the curable composition on the substrate, and
the controller sets the attraction force generator in a non-operation state at least in the curing.

4. The apparatus according to claim 2, wherein
the processing includes driving the substrate, and curing the curable composition by applying curing energy to the curable composition on the substrate, and
the controller makes the attraction force generated by the attraction force generator in the curing smaller than the attraction force generated by the attraction force generator in the driving.

5. The apparatus according to claim 1, wherein
the attraction force generator includes a first portion provided on the movable stage and a second portion provided on the substrate holder, and generates the attraction force between the first portion and the second portion,
the coupling further includes an elastic member, and
the elastic member supports one of the first portion and the second portion such that when the attraction force generator generates the attraction force, the first portion and the second portion come into contact with each other, and when the attraction force generator does not generate the attraction force, the first portion and the second portion do not come into contact with each other.

6. The apparatus according to claim 5, wherein
the elastic member includes a leaf spring.

7. The apparatus according to claim 1, wherein
the attraction force generator includes a first portion provided on the movable stage and a second portion provided on the substrate holder, and generates the attraction force between the first portion and the second portion,
the first portion includes an elastic member, and
the first portion is configured such that when the attraction force generator generates the attraction force, the first portion and the second portion come into contact with each other, and when the attraction force generator does not generate the attraction force, the first portion and the second portion do not come into contact with each other.

8. The apparatus according to claim 1, wherein
the attraction force includes at least one of an electrostatic attraction force, a vacuum attraction force, and an electromagnetic attraction force.

9. The apparatus according to claim 1, further comprising a driving mechanism configured to drive the movable stage,
wherein the attraction force generator is set in an operation state when the movable stage is driven by the driving mechanism.

10. The apparatus according to claim 1, wherein the film forming apparatus is formed as a planarization apparatus.

11. The apparatus according to claim 1, wherein the film forming apparatus is formed as an imprint apparatus.

12. An article manufacturing method comprising:
forming a cured product film on a substrate using a film forming apparatus defined in claim 1; and
performing processing for the substrate that has undergone the forming, thereby obtaining an article.
